(19) United States
(12) Patent Application Publication
(10) Pub. No.: US 2014/0043053 A1
(43) Pub. Date: Feb. 13, 2014

(54) DOCKING DEVICE, DOCKING METHOD

(71) Applicants: Werner Huber, Nussdorf am Inn (DE); Yusman Sugianto, Singapore (SG); Cheng Khoon Clement Sng, Singapore (SG)

(72) Inventors: Werner Huber, Nussdorf am Inn (DE); Yusman Sugianto, Singapore (SG); Cheng Khoon Clement Sng, Singapore (SG)

(73) Assignee: ESMO AG, Rosenheim (DE)

(21) Appl. No.: 14/005,054

(22) PCT Filed: Mar. 13, 2012
(86) PCT No.: PCT/EP2012/054361

§ 371 Date: Oct. 30, 2013

(30) Foreign Application Priority Data
Mar. 16, 2011 (DE) 10 2011 014 148.0

(51) Int. Cl. G01R 1/04; G01R 31/26

(52) U.S. Cl. CPC G01R 1/0408; G01R 31/2601
USPC 324/750.16

(57) ABSTRACT

A docking device for connecting a semiconductor probe to a semiconductor handler has in each case one probe-side and one handler-side connecting device, a handling device for handling a contact-making device and a coupling device for coupling the connecting devices. The coupling device has a first shifting device, which allows the translational and guided shifting of the probe-side connecting device relative to the handler-side connecting device towards and away from one another.

### CROSS-REFERENCE TO RELATED APPLICATIONS

This application is the US National Stage of International Application No. PCT/EP2012/054361, filed on 13 Mar. 2012, which designated the United States of America and which was published under PCT Article (2) as Publication No. WO 2012/123443 and which claims priority to and the benefit of German Application No. 10 2011 014 148.0, filed 16 Mar. 2011, the disclosures of which are incorporated herein by reference in their entireties.

### BACKGROUND

1. Field

The aspects of the disclosed embodiments relate to a docking device and a docking method.

2. Brief Description of Related Developments

A docking device serves for connecting a semiconductor test head to a semiconductor handler as well as for handling further components which are necessary for the testing of semiconductors.

FIG. 2 shows the situation altogether schematically. 1 is a semiconductor handler which supplies semiconductors to a test station 21 in the handler. The semiconductors to be tested can be complex semiconductors such as complex analogue circuits and/or digital processors which can have a plurality of terminals (n>100 or >200). 2 symbolizes a test head having suitable testing electronics. 23 symbolizes a DUT board (DUT=“device under test”) serving for the electrical contacting or connecting of the electronic system in the test head 2 with the semiconductor to be tested (“device under test”) in the semiconductor handler 1. A docking device 10 serves, on the one hand, for the mechanical connection of semiconductor handler 1 and test head 2, but also especially for handling the DUT board. 3 is a manipulator by means of which the test head 2 can be moved, positioned and held.

The test heads, just like the semiconductor handlers, can also be complex equipment which can have masses of many 100 kilograms to more than 1 ton. In order to be able to reliably electrically contact the semiconductor device to be tested, a stable and mechanically precisely defined mechanical connection between semiconductor handler 1 and test head 2 must also be given which, in spite of the high weight, must be precise and stable.

There have been known docking devices which have a handler-side fixing device 11 and a test head-side fixing device 12. These are, on their part, connected via a device 13 with each and individually with the handler 1 and the test head 2. In the centre they have a passage which receives the DUT board.

Document EP 1495339 B1 describes an automatic testing system in which a base component is swivel-mounted to an automated test system. The base component serves for connecting the test head and the test system and also carries the DUT board.

The disadvantage of this setup is the swivel movement, since, on the one hand, at the end remote from the swivel axis high excursions are necessary for obtaining the desired distance of regions also closer to the swivel axis. A further disadvantage is that due to the alignment the DUT board can drop out during unlocking. What is also disadvantageous is that during the swivel movement the test head can, for practical reasons, not be carried along, so that before the swivelling the test head must be separated from the system, so that for individual tests the electric interface towards the test head is no longer available. A further disadvantage is that, when the base plate is swivelled away, the opening in the semiconductor handler is exposed which can take in moisture, what can lead to the immediate condensation in cold tests (which can be run up to −60° C.) and, then, to possibly necessary extensive cleaning work.

### SUMMARY

One aspect of the disclosed embodiments provides a docking device and a docking method which requires a short travel path for opening the system, and/or which prevents a dropping-out of the DUT board, and/or which, also when the system is separated, keeps the electric interface towards the test head accessible and/or which finally reduces the penetration of moisture into the semiconductor handler.

For the connection of a semiconductor test head to a semiconductor handler, a docking device comprises a test head-side connecting device and a handler-side connecting device, a handling device for handling a contact-making device (DUT board) for electrically connecting a semiconductor with contacts of the test head, a coupling device for coupling the test head-side connecting device with the handler-side connecting device, a first shifting device which allows the translationally guided shifting of the test head-side connecting device relative to the handler-side connecting device towards and away from each other.

Through the translational shifting of the two connecting devices relative to each other a comparatively short travel distance is required which can also be followed by the test head and the regularly present manipulator. Moreover, when the components approach each other, possibly resilient contact pins are not laterally displaced, but only compressed in correspondence with their longitudinal direction, so that a more reliable contacting is ensured.

A docking device comprising test head-side and handler-side connecting devices, a handling device and a coupling device as described above shows a moving mechanism for moving the contact-making device between a working position and an exchange position, and/or has an alignment mechanism for aligning the contact-making device in the exchange position into a removal orientation.

By means of the alignment mechanism the contact-making device can be aligned before its removal from the handling device in such a way that, before its removal and also before its unlocking from the handling device, it remains in the handling device due to gravitation alone, so that it cannot drop out by itself.

A docking device having a test head-side and a handler-side connecting device, a handling device and a coupling device as described may be designed in such a way that, when the system is separated, the handling device is carried along with the test head-side connecting device by being mounted thereon. Then, also the contact-making device is carried along with the test head-side connecting device accordingly. In this way the electric interfaces to the test head are accessible, so that also individual tests can be run which are performed independently of the semiconductor handler.

A docking device for connecting a semiconductor test head to a semiconductor handler comprises a handling device for handling a contact-making device. Moreover, it comprises an actuatable covering device for covering or exposing an opening of the semiconductor handler which can be occupied by the contact-making device.

By covering the opening in the semiconductor handler the air exchange between the interior and the exterior of the semiconductor handler is at least reduced so that, accordingly, also the moisture flowing into the handler is reduced, so that the icing of handler components in cold tests is at least reduced.

A docking method has the following steps:

possibly unlocking the taken closed position of the docking device and translationally separating the connecting devices perpendicularly away from each other, moving the handling device relative to the connecting device, to which it is mounted, perpendicularly away from each other,
laterally moving the contact-making device by means of the handling device,
possibly swivelling the alignment mechanism, so that the contact-making device is held by the force of gravity alone, when the holding means is released, releasing the holding means,
inserting a contact-making device and locking the holding means,
possibly swivelling the alignment mechanism backwards into the initial position and possibly locking the same in this position,
moving the handling mechanism from the exchange position into the working position,
translationally moving the handling mechanism perpendicularly towards the connecting device to which it is mounted, and
translationally moving the connecting devices perpendicularly towards each other and possibly locking this position.

### BRIEF DESCRIPTION OF THE DRAWINGS

Subsequently, embodiments of the invention are described with reference to the drawings.

FIG. 1 perspectively shows in detail a lateral view of an embodiment of a docking device,

FIG. 2 schematically shows the overall structure, and

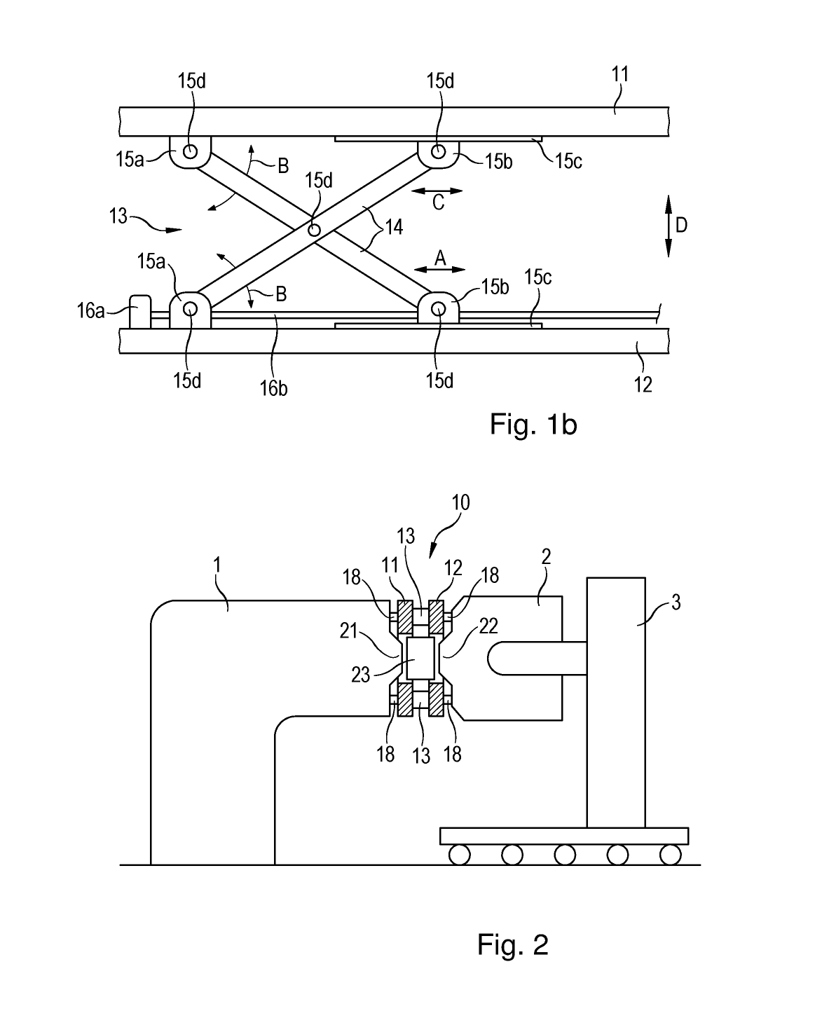

FIG. 3 shows a lateral view of the docking device.

### DETAILED DESCRIPTION OF THE DISCLOSED EMBODIMENTS

Same reference numerals in this description designate same components. Aspects of the disclosed embodiments are to be regarded as combinable with each other, even if this is not expressly said, as far as their combination is not out of question for technical reasons.

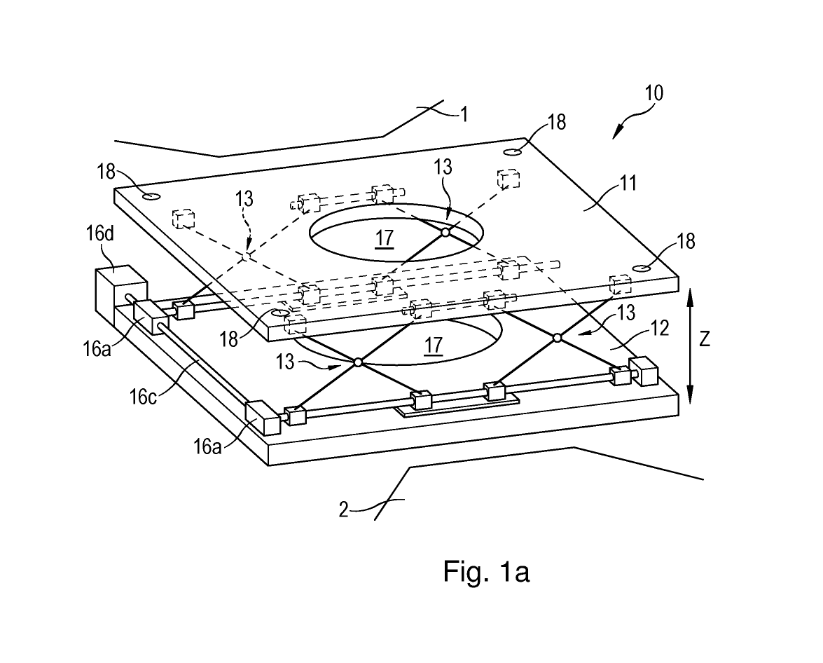

FIG. 1a schematically shows a perspective of a docking device 10. It shows a handler-side connecting device 11 and a test head-side connecting device 12. The connecting devices each serve for effecting a mechanically stable, fixed and preferably rigid connection to the test head 2 or to the handler 1. The connecting devices can have plate-shaped or frame-shaped or U-shaped base bodies which may be made from solid metal plates or may be in one-piece form, so that they are rigid in themselves and, if appropriate, also serve for stiffening the respective access faces of the handler or the test head. The connection of the respective connecting devices towards the handler or the test head can be effected by connectors 18, e.g. screw connections or the like.

The mentioned connecting devices 11 and 12 are, for their part, coupled with each other via a coupling device 13-16. The coupling device comprises a shifting device which allows the translational and guided shifting of the test head-side connecting device relative to the handler-side connecting device towards and away from each other. In FIG. 1a the coupling device allows a movement in vertical direction indicated by arrow Z. 17 denotes openings provided in the connecting devices 11 and 12, in which, in use, the electrical contact-making device 23 (DUT board) comes to rest. What is not shown, but what is also present, is a handling device for handling the contact-making device, in particular for moving the contact-making device 23 into a position which is necessary for contacting, on the one hand, the test head 2, and on the other hand, the semiconductor 1 to be tested.

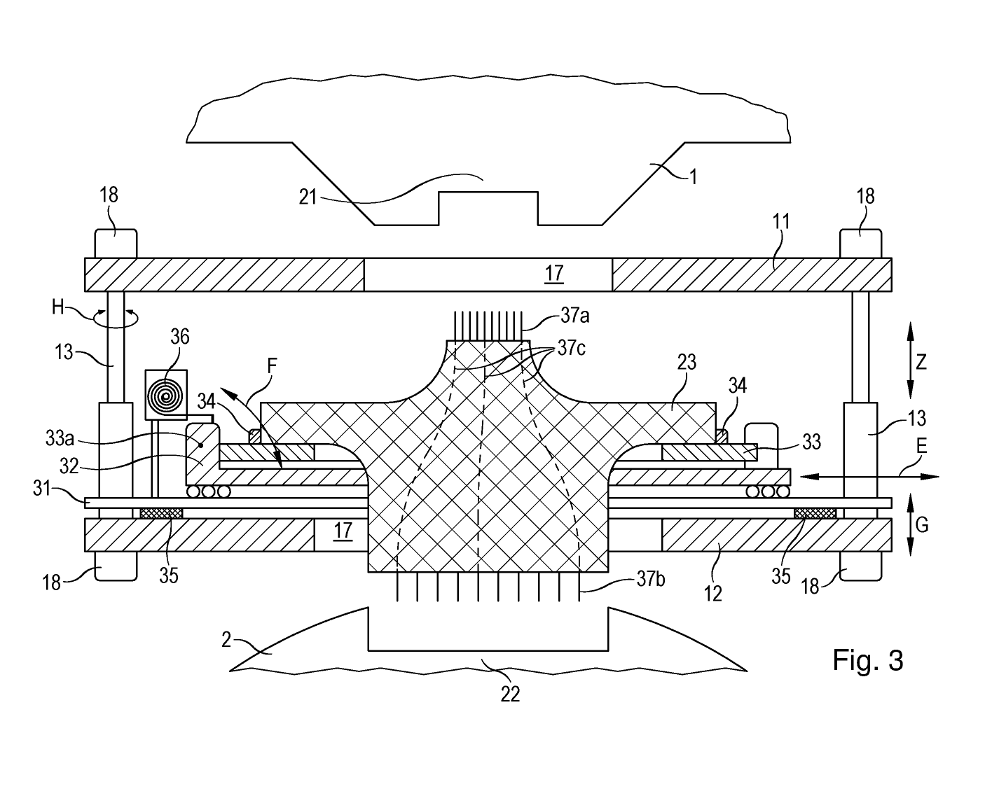

The coupling device 13 can be constructed in various ways. The shifting device can comprise a plurality of actuators disposed at different locations of the connecting devices 11, 12. They can be disposed, particularly, at marginal regions or corner regions of the connecting devices or can be mounted to the front faces thereof. There can be provided three or more actuators. The actuators can be driven synchronously. Each actuator can have a helical gear (screwing movement indicated by arrow H in FIG. 3) or a shearing mechanism (FIG. 1a, b) or a hydraulic piston or a pneumatic piston, each, if appropriate, with associated signal and power supply system, control system, sensors and actuators.

FIG. 1a shows a shearing mechanism which is shown in more detail in lateral view in FIG. 1b. 15a designates fixedly localized bearings, each one of which being fixedly localized at respectively one connecting device 11, 12. 15b shows shiftable pivot bearings which are shiftable along rails 15c in the direction of the arrow C. 15d designates respective rotational axes. 14 denotes shear arms which are attached crosswise and are connected to each other via a rotational axis 15d. 16 designates a drive mechanism which can, e.g., be a helical gear. A threaded rod 16b is made to rotate by a drive 16a and, in this way, effects a shifting of the movable bearing 15b at the connecting device 12 along the rail 15c and, particularly, along the direction of arrow A. Accordingly, the shear legs 14 perform rotational movements along arrows B, one of which carries along the shiftable bearing 15b above at the connecting device 11 along arrow C. In this way, altogether, a vertical movement in the drawing plane along arrow D is performed.

In FIG. 1a 16d denotes a drive which can, e.g., be an electric motor, the output shaft of which is connected to the shaft 16c which, on its part, is connected via converters 16a with the shafts 16b of the helical gear, which, then, drive the shears. However, the drive can also be a hydraulic pump or a fluid pump or fluid control, e.g. for externally supplied compressed air or fluids.

The vertical movement can be used for connecting the system or for opening/separating the system. In the case of a connection (=closing), the contact-making device approaches the respectively provided contact points in the handler 1 and in the head 2. When the system is connected, first the contact-making device is moved into the intended position by the handling device. Beforehand, the connecting devices were mounted to the test head and the handler, respectively. When the contact-making device is in the intended position, the connecting devices are moved towards each other, so that, accordingly, test head and semiconductor handler also move towards each other.

The contact-making device can comprise spring-loaded contact pins (“pogo pins”) which are compressed against the spring effect when the two connecting devices are brought together and, accordingly, reliably contact their respective contact positions. There can be provided a plurality of contact pins (n>100 or >200 or >500), and the force applied to them can be considerable per pin (F>0.1N or >0.2N or >0.5N per pin). Insofar, it is pointed out that, when the two connecting devices are brought together, often only the contact towards the test head is made, whereas the contacts towards the semiconductor device to be tested still remain free. The contacting is then effected by an automatic mechanism within the handler.

Differently from what is shown in FIG. 1a, the actuators can also be hydraulic or pneumatic pistons. They have to overcome at least frictional forces and the forces necessary for compressing the contact pins, and possibly, according to the alignment of the overall system, have to fully or proportionately overcome also weight forces which, in the case of the test head, can be higher than 5.000 N (corresponding to a mass of 500 kg). In particular, three pneumatic pistons can be provided, two of which are located at two adjacent corners of the connecting devices, and a third one is located at an opposite side. Even a helical gear is possible as an actuator.

In addition to the shifting device one or more guiding means can be provided which can comprise one or more slideways which make possible the sliding along the desired direction of movement (towards and away from each other), but prevent a movement perpendicularly thereto. Then, the actuators are relieved.

There can be provided sensors which qualitatively or quantitatively detect the travel path of the connecting devices relative towards or away from each other. Furthermore, a control system can be provided which controls the actuators in dependence of the sensor system. The sensor system can be or comprise an end switch and, in this way, can qualitatively detect particular positions (initial position and/or end position), or it can be a quantitative path sensor.

According to the system design the control can be an on/off control of the individual actuators. They can also be speed-controlled. The individual actuators can be individually or collectively closed-loop controlled or open-loop controlled, when their matching to each other sufficiently precisely ensues otherwise, e.g. by settings made by the manufacturer, mechanical coupling, or the like.

In addition to the translational movement a rotational relative movement between the connecting devices can (but need not) be provided. If it takes place, it can be designed such that it only occurs when spring-loaded contact pins of the contact-making device are not in touch with contact positions in the handler or in the test head.

FIG. 3 shows in a schematic lateral view the docking device 10. The lateral view now also shows the handling device 31-35 which is depicted with inserted contact-making device 23. The contact-making device becomes manageable through the handling device 31-35, in particular because it can be pushed into the system from laterally outside or pulled out thereof by its being able to be moved between the two connecting devices 11 and 12. The method is performed between a working position, in which the contact-making device 23 takes its target position relative to the test head 2 and relative to the handler 1, and an exchange position, which lies outside of the space between the connecting devices 11, 12 and in which the contact-making device 23 can be removed, inserted or exchanged.

37a designates electrical contact pins (preferably compressible, resilient, spring-loaded) of the contact-making device 23 which can be designed for electrically contacting a chip to be tested, 37b designates electrical contact pins (preferably compressible, resilient, spring-loaded) which can be designed for electrically contacting components in the test head, and 37c symbolizes electrical connections between them.

The handling device has a moving mechanism 31, 32 which serves for moving the contact-making device 23 between the working position and the exchange position. The moving mechanism can comprise one or more rails 31 and a carriage 32 running thereon. In the embodiment of FIG. 3 the movement is effected horizontally in the drawing plane along arrow E. The rails 31 can be telescopable, so that a movement completely out of the intermediate space between the connecting devices 11, 12 is possible.

At the carriage 32 or instead thereof an alignment mechanism 33 can be provided by which, possibly in the exchange position, the contact-making device 23 can be aligned into a position in which it cannot drop out if it is unlocked before the removal. There is provided a holding means 34 by which the contact-making device 23 can be locked or unlocked at the alignment mechanism, so that, during use, the contact-making device 23 is retained.

When the contact-making device 23 is exchanged, the holding means 34 must be released. In order to prevent the contact-making device 23 from dropping out in this situation, the alignment mechanism 33 is provided which is, e.g., pivotable about an axis 33a at the carriage 32. In this way the alignment mechanism 33 can be swivelled into a position in which the contact-making device 23 is held in its position by gravitation alone, even if the holding means 34 is unlocked. There can be provided one or more rotational axes 33a which, in this case, are not parallel to each other. Furthermore, a not shown locking device can be provided in order to retain the alignment mechanism 33, on the one hand, in the working orientation (as shown in FIG. 3), and on the other hand, in the desired exchange orientation, if it is outside of the space between the connecting devices.

The handling device 31-35 is mounted to one of the connecting devices 11, 12, preferably to the test head-side connecting device 12. It may comprise a second shifting device 35 by means of which the handling device can be shifted relative to the connecting device to which it is mounted, in particular towards the same and away therefrom (arrow G in FIG. 3). For the second shifting device 35 the same statements hold true as were made with regard to the first shifting device, with the exception of the components shifted relative to each other, i.e. in particular with regard to design options, structural features, drive and actuation. In FIG. 3 it is only shown as a block-like component between the head-side connecting device 12 and the rail 31.

The docking device can comprise an actuatable covering device 36 by which an opening in the handler can be covered or totally or partially closed. The handler can be adapted to cool semiconductors to very low temperatures during the semiconductor test. Temperatures down to −40° C. or even down to −60° C. are common. If, during such a test, the system is opened, ambient air reaches the cold parts of the handler, if there have not been taken precautions. The moisture in the ambient air will then immediately freeze and lead to an ice coating in the interior of the handler. Depending on the duration and the air moisture this can lead to long operational interruptions (thawing, renewed cooling).

In order to prevent this, an actuatable covering device 36 is provided which can cover or completely or partially close an opening of the semiconductor handler with a plane cover element. It is attached to the docking device 10 and can be designed to be actuated together with the actuation of the handling device. This can be, e.g., a roller blind mechanism which, at one side of the handler opening, holds a cover foil rolled up and being reversibly extendable. The actuation can also be effected manually or automatically, independently of the actuation of the handling device. It can be a translationally movable shifting mechanism or a foil or cover which is held at one side and folded in the way of accordion bellows (zigzag-like).

The covering can be effected in such a way that the covering device (e.g. the unrolled blind foil or a cover, slide or accordion mechanism) is held at a greater or lesser distance (up to a distance of 0) to the opening of the handler. A noticeable success is already achieved when a foil is kept at a particular distance from the opening. In this way the penetration of ambient air into the handler is reduced, so that accordingly also the entry of moisture and the heat exchange is decreased.

The covering device or the cover can be of a cold-resistant material, in particular a material being flexible at low temperatures, which will not become brittle at these low temperatures (−40° C., −60° C.). It can be a plastic material. Moreover, the material can be heat-insulating for reducing the temperature equalization. Preferably, the material is air-tight and moisture-proof.

The exchange of a contact-making device 23 out of a working position can, thus, altogether comprise the subsequently described steps. One starts from a situation in which the individual connecting devices 11, 12 are attached to their components (handler, test head), respectively, and the system is closed by the connecting devices being moved towards each other as far as possible.

Possibly unlocking the taken position and translationally separating the connecting devices 11 and 12 from each other along the direction of the arrow Z by means of the first shifting device 13-16. In this way the connecting devices 11, 12 gain a distance from each other, but are still attached to each other by the first shifting device 13-16. The travel distance is that large that a gap is formed which is large enough for the contact-making device 23 being movable between the plates 11, 12. When the two connecting devices 11, 12 are moved apart, the handling device 31-35 is carried along by one of the two. Preferably, this is the head-side connecting device 12.

Moving the handling device 31-35 relative to the connecting device to which it is mounted (and, thus, indirectly, of course, also relative to the other connecting device) by means of the second shifting device 35. In FIG. 3 this corresponds to a movement of the handling device 31-35 along the arrow G upwards. In this way the contact-making device 23 (DUT board) is lifted into the free space between the two connecting devices 11, 12 in such a way that it can be laterally moved there in FIG. 3.

Laterally moving the contact-making device 23 by means of the handling device 31-35 along the rails 31 which are preferably telescopable. In FIG. 3 this can take place along the direction of arrow E, e.g. to the right in the drawing plane beyond the right-side ends of the connecting devices 11, 12. The method can be performed by means of an automatic drive or manually.

Swivelling the alignment mechanism 33 in such a way that the contact-making device 23 is held by the force of gravity alone, when the holding means 34 is released. The swivelling can take place around the rotational axis 33a according to arrow F in FIG. 3. E.g. the movement along 3E to the right in FIG. 3 can, in reality, be a movement downwards. By swivelling the alignment mechanism 33 about axis 33a a position can be taken in the exchange orientation, in which the contact-making device 23 cannot drop out when the holding means 34 is released.

Releasing the holding means 34. As a result, the contact-making device 23 lies loosely in the alignment mechanism 33 and can be removed.

Inserting another contact-making device 23 and locking the holding means 34.

Swivelling the alignment mechanism 33 backwards into the initial position and, possibly, locking the same in this position.

Moving the handling mechanism from the exchange position into the working position along arrow E (in FIG. 3 assumed leftwards as far as to the position shown in FIG. 3).

Moving the handling mechanism towards the connecting device to which it is mounted (in FIG. 3 head-side connecting device 12).

Moving the connecting devices 11, 12 towards each other along the arrow Z and possibly locking this position.

At suitable points of time, an opening in the handler can be covered or exposed, e.g., in or directly before or after the steps c) and h).

The first-time connection (“docking”) of handler and tester can comprise the following steps:

k) Connecting the head-side connecting device 12 with the test head 12, and the handler-side connecting device 11 with the handler 11. Since the two connecting devices are, for their part, connected to each other, the overall system is connected with each other.

l) There follow the above described steps a) to d), when, as usual, the docking device is supported out of operation in the “closed” state (fixing devices lie close to each other). Otherwise, step a) and possibly also step b) are not necessary, since the respective end positions have already been taken.

m) There follow steps f) to j).

Apart from the mounting of the docking device to head and handler and apart from the exchange of the contact-making device, the above sequence can be effected fully automatically or partially automatically or preferentially manually.

The exchange of a contact-making device 23 out of the working position can, therefore, altogether comprise the subsequently described steps. One starts from a situation in which the individual connecting devices 11, 12 are each mounted to their components (handler, test head) and the system is closed by the connecting devices being moved towards each other as far as possible.

The docking device can have one or more sensors (not shown) for detecting the shift of the first and/or the second shifting device and/or the travel distance of the moving means. It can also comprise one or more control systems for open-loop controlling and/or closed-loop controlling the shift of the first and/or second shifting device and/or the travel distance of the moving means and/or of locks. By means of the control system, steps of the docking method can be performed fully or partially automatically.

1. (canceled)

2. A docking device for connecting a semiconductor test head to a semiconductor handler, comprising:
a test head-side connecting device for connecting the docking device with the test head,
a handler-side connecting device for connecting the docking device with the handler,
a handling device for handling a contact-making device for electrically connecting a semiconductor with contacts of the test head,
a coupling device for coupling the test head-side connecting device to the handler-side connecting device,
wherein the coupling device has a first shifting device which allows the translational and guided shifting of the test head-side connecting device relative to the handler-side connecting device towards and away from each other.

3. The docking device according to claim 2, wherein the first shifting device comprises a plurality of first actuators disposed at different locations of the connecting devices, preferably at their corner regions and/or marginal regions, acting in parallel directions, which can be driven synchronously and can each comprise a helical gear or a shearing mechanism or hydraulic or pneumatic pistons.

4. The docking device according to claim 2, wherein the first shifting device comprises three hydraulic or pneumatic cylinders, two of which being located in adjacent corner regions of the connecting devices, and a third one being located at a side of the connecting devices, which faces the two corners.

5. The docking device according to claim 2, further comprising one or more guiding devices which guide the translational shifting.

6. A docking device for connecting a semiconductor test head to a semiconductor handler according to claim 2, comprising:
a test head-side connecting device for connecting the docking device with the test head,
a handler-side connecting device for connecting the docking device with the handler,
a handling device for holding, aligning and handling a contact-making device for electrically connecting a semiconductor with contacts of the test head,
a coupling device for coupling the test head-side connecting device to the handler-side connecting device,
wherein the handling device has a moving mechanism for moving the contact-making device between a working position and an exchange position, and/or an alignment mechanism for aligning the contact-making device in the exchange position into a removal orientation.

7. The docking device according to claim 6, wherein the handling device comprises a holding means for releasably holding the contact-making device, in particular at the alignment mechanism.

8. The docking device according to claim 6, further comprising a locking device for keeping the alignment mechanism in the exchange orientation.

9. The docking device according to claim 6, wherein the alignment mechanism is adapted for aligning the position of the contact-making device by swivelling about one or two rotational axes.

10. The docking device according to claim 6, wherein the handling device is mounted to one of the connecting devices and comprises a second shifting device for shifting the handling device towards and away from the connecting device.

11. The docking device according to claim 10, wherein the second shifting device comprises a plurality of second actuators disposed at different locations of the handling device, preferably at its corner regions and/or marginal regions, acting in parallel directions, which can be driven synchronously and can each comprise a helical gear or a shearing mechanism or hydraulic or pneumatic pistons.

12. The docking device according to claim 6, wherein the moving mechanism comprises one or more preferably telescopable rails and a carriage running along the rails, which comprises the alignment mechanism.

13. The docking device according to claim 12, wherein the moving mechanism comprises a drive system for moving the carriage.

14. A docking device for connecting a semiconductor test head to a semiconductor handler according to claim 2, comprising:
test head-side connecting device for connecting the docking device with the test head,
a handler-side connecting device for connecting the docking device with the handler,
a handling device for handling a contact-making device for electrically connecting a semiconductor with contacts of the test head,
a coupling device for coupling the test head-side connecting device to the handler-side connecting device,
wherein the handling device is mounted to the test head-side connecting device and can be shiftable relative thereto.

15. The docking device according to claim 14, wherein the handling device comprises a second shifting device for shifting the handling device towards and away from the connecting device.

16. The docking device according to claim 15, wherein the second shifting device comprises a plurality of second actuators disposed at different locations of the handling device, acting in parallel directions, which can be driven synchronously and can each comprise a helical gear or a shearing mechanism or hydraulic or pneumatic pistons.

17. A docking device for connecting a semiconductor test head to a semiconductor handler according to claim 2, comprising:
a test head-side connecting device for connecting the docking device (10) with the test head,
a handler-side connecting device for connecting the docking device with the handler,
a handling device for handling a contact-making device for electrically connecting a semiconductor with contacts of the test head,
a coupling device for coupling the test-head-side connecting device to the handler-side connecting device,
wherein an actuatable covering device for covering or exposing an opening of the semiconductor handler, which can be occupied by the contact-making device.

18. The docking device according to claim 17, wherein the covering device comprises a roller blind mechanism.

19. The docking device according to claim 18, wherein the roller blind mechanism is connected to the moving mechanism in such a way that it is actuated together with the moving mechanism.

20. The docking device according to claim 17, characterized in that the covering device covers the opening of the semiconductor handler at a distance thereto.

21. The docking device according to claim 17, wherein the roller blind mechanism comprises a cold-resistant and/or thermally insulating blind material.

22. The docking device according to claim 17, wherein the covering device comprises a cover for closing the opening of the semiconductor handler.

23. The docking device (10) according to claim 2, wherein one or both connecting devices are constructed to have a plate shape or frame shape or U-shape, and may have a one-piece base body, and comprise connectors for the connection to the test head or to the handler, and preferably have a central opening which is dimensioned and adapted for receiving the contact-making device.

24. The docking device according to claim 2, wherein the handling device comprises a moving mechanism with one or more rails preferably mounted to the test head-side connecting device and extending in a first direction, and a carriage movable along the rails, wherein the carriage has is a receiving means for the contact-making device, and the receiving means may comprise a locking mechanism for the contact-making device.

25. The docking device according to claim 24, wherein the receiving means is slewable about one or more rotational axes relative to the carriage and can be locked in one or more positions.

26. The docking device according to claim 24, wherein the handling device comprises a second shifting device for shifting the contact-making device relative to one of the connecting devices along a second direction, wherein a holding means may be provided for holding the contact-making device in one or more positions along the second direction.

27. The docking device according to claim 2, further comprising one or more sensors for detecting the shift of the first and/or second shifting device and/or the travel distance of the moving device.

28. The docking device according to claim 2, further comprising one or more control systems for open-loop and/or closed-loop controlling the shift of the first and/or the second shifting device and/or the travel distance of the moving device.

29. A docking method comprising:
mounting a docking device according to claim 2 to the test head and to the handler,
possibly unlocking the taken closed position of the docking device and translationally separating the connecting devices from each other,
possibly moving the handling device relative to the connecting device to which it is mounted,
laterally moving the contact-making device by means of the handling device,
possibly swivelling the alignment mechanism, so that the contact-making device is held by the force of gravity alone, when the holding means is released,
releasing the holding means,
inserting a contact-making device and locking the holding means,
possibly swivelling the alignment mechanism backwards into the initial position and possibly locking the same in this position,
moving the handling mechanism from the exchange position into the working position,
translationally moving the handling mechanism towards the connecting device to which it is mounted, and
translationally moving the connecting devices towards each other and possibly locking this position.
